(19) United States
(12) Patent Application Publication
(10) Pub. No.: US 2004/0217451 A1
(43) Pub. Date: Nov. 4, 2004

(54) Semiconductor packaging structure

(76) Inventors: Sai-Mun Lee, Penang (MY); Gurbir Singh, Penang (MY); Cheng Why Tan, Bukit Mertajam (MY)

Correspondence Address: AGILENT TECHNOLOGIES, INC., Legal Department, DL429, Intellectual Property Administration, P.O. Box 7599, Loveland, CO, 80537-0599, US

(21) Appl. No.: 10/649,006

(22) Filed: Aug. 26, 2003

(30) Foreign Application Priority Data
Nov. 14, 2002 (MY) PI 20024261

(51) Int. Cl. H01L 23/495

(52) U.S. Cl. 257/666

(57) ABSTRACT

A packaging structure for a semiconductor device includes a substrate surface-mountable on a mounting surface of a circuit board. The substrate has a first side facing away from the mounting surface and a second side being on the same side of the structure as the mounting surface. A recess is formed in the second side of the substrate. A semiconductor die having a first side and a second side is mounted in the recess, with the first side of the semiconductor die facing away from the mounting surface and a portion of the first side of the semiconductor die bonded to the substrate within the recess.

### FIELD OF INVENTION

The invention relates generally to the field of electronic component packaging, and more particularly, to a semiconductor packaging structure, for instance a sensor package.

### BACKGROUND OF THE INVENTION

Semiconductor packaging sometimes involves a substrate recessed from a first side, with a semiconductor die mounted in that recess. A second, opposing side of the substrate has electrical connections to allow it to be mounted onto a circuit board. Such an approach is exemplified by a known image sensor package shown in FIG. 1.

A SiGe sensor die 10 is placed within an upwardly recessed ceramic substrate 12, on the top surface of a substrate base 14. The active surface 16 of the sensor die 10, which is responsive to electromagnetic radiation, faces upwards. The underside of the sensor die 10 is attached to the substrate base 14 using an epoxy 18. The active surface 16 of the die is connected to contacts 20 on the top surface of the substrate base 14 by way of gold interconnect wires 22, which loop upwards, outwards and downwards. The whole sensor is then sealed by way of a cover glass 24 over the entire recessed portion. The contacts 20 extend through to the underside of the substrate, to allow the package to be surface mounted.

Such a packaging process requires special ceramic material for the substrate, which is relatively more expensive than other materials, such as organic substrates. Moreover, the package size is relatively large, as a result of the wire bonding being used as the first level interconnects. This is because space has to be allocated for good wire loop formation and also clearance for the wire bond capillary. Further, in this conventional package, the use of wire bonding contributes to increasing the inductance and capacitance of the electrical connections, which affects the overall package performance.

### SUMMARY OF THE INVENTION

The invention is directed to overcoming or at least partially alleviating one or more of the drawbacks set forth above.

According to one aspect of the invention, there is provided a packaging structure for a semiconductor device. The packaging structure has a mounting surface for mounting on a circuit board. A substrate having a first side and a second side is included. The first side of the substrate faces away from the mounting surface and the second side of the substrate faces towards the mounting surface. A recess in at least the second side of the substrate is provided. A semiconductor die having a first side and a second side is mounted in the recess, with the first side of the die facing away from the mounting surface. A portion of the first side of the semiconductor die is electrically bonded to a surface of the recess.

### BRIEF DESCRIPTION OF THE DRAWINGS

The invention will now be further described by way of non-limiting examples with reference to the accompanying drawings, in which:

FIG. 1 is a cross-sectional view of a conventional image sensor package;

FIG. 2 is a cross-sectional view of a semiconductor packaging structure in accordance with a first embodiment of the invention;

FIG. 3 is a view of the semiconductor packaging structure of FIG. 2, through line 3-3 of FIG. 2;

FIG. 4 is a view of an edge portion of the semiconductor packaging structure of FIG. 2, through line 4-4 of FIG. 2;

FIG. 5 is a cross-sectional view of a semiconductor packaging structure in accordance with a second embodiment of the invention;

FIG. 6 is a cross-sectional view of a semiconductor packaging structure in accordance with a third embodiment of the invention; and.

FIG. 7 is a flow chart relating to a method of assembling the packaging structure of the invention.

### DETAILED DESCRIPTION

Several embodiments of the present invention are now described. In the following detailed description, where the embodiments have the same or similar elements, these are labelled with the same reference numbers and should be construed accordingly.

Embodiments of the invention provide solutions to drawbacks of conventional packages by attending to aspects of the prior art such as the cost of the package and the physical size of the package.

The preferred embodiments of the invention relate specifically to image sensor packages. However, the invention is applicable to other packaging.

According to one aspect of the invention, there is provided a packaging structure for a semiconductor device. The packaging structure has a mounting surface for mounting on a circuit board. A substrate having a first side and a second side is included. The first side of the substrate faces away from the mounting surface and the second side of the substrate faces towards the mounting surface. A recess in at least the second side of the substrate is provided. A semiconductor die having a first side and a second side is mounted in the recess, with the first side of the die facing away from the mounting surface. A portion of the first side of the semiconductor die is electrically bonded to a surface of the recess.

Preferably, the recess includes an exposed portion of the substrate facing the mounting surface and the portion of the first side of the die is bonded to the exposed portion.

For some structures, the substrate may be made up of two layers, with a hole through a first layer connecting to the recess which is in the second layer. The hole through the first layer is preferably smaller than the recess in the second layer. This leaves an exposed portion of the first layer, to which the upper surface of the die is electrically bonded.

Usefully, the structure may have a sealant sealing between the edges of the die and the substrate.

Instead or as well, the structure may further comprise a thermally conductive and electrically insulating encapsulant in the recess portion, beneath the die.

The structure may be used with a sensor chip die. In which case, a non-opaque portion cover over the die is useful.

According to a second aspect of the invention, there is provided a packaging structure comprising: a first substrate having a first surface and a second surface, with electrical connections on the second surface. A second substrate has a first surface and a second surface with electrical connections running from first surface to mounting pads on the second surface, the mounting pads for mounting onto a printed circuit board. A die with first and second surfaces has electrical connections on its first surface. The first surface of the second substrate is mounted to the second surface of the first substrate, with the electrical connections of the first substrate in electrical contact with the electrical connections of the second substrate. The die is mounted to the second surface of the first substrate, with the electrical connections on the die fixedly and electrically attached to the electrical connections of the second surface of the first substrate. In addition, there is a sealant for sealing the first surface of the die from its bottom surface.

According to another aspect of the invention, there is provided a method of assembling a semiconductor device packaging structure. This method includes providing a substrate having a first side, an opposed second side for surface mounting on a printed circuit board and a recess in the second side. A semiconductor die is inserted into the recess and it is mounted and electrically bonded to a surface of the recess.

According to again another aspect of the invention, there is provided a method of assembling a semiconductor device packaging structure. A semiconductor die is inserted into a recessed side of a substrate and mounted and electrically bonded to the recess and the recessed side of the substrate is then surface mounted onto a printed circuit board.

Thus there may be provided a packaging structure, for instance for an image sensor, having a first substrate having a top surface and a bottom surface and a plurality of metallized pads and traces and a second substrate having a plurality of vias arranged on one of its surfaces for mounting onto a printed circuit board. A die having an active area on its top surface and bumps/bond pads at its edges is fixedly attached to the first substrate. A sealant between the substrate and edges of the die encloses the active area of the die from below and cover glass fixedly attached to the top surface of the first substrate encloses it from above. A thermally conductive material may be deposited around the bottom surface of the die so as to enhance thermal dissipation from the die to a PCB.

The invention offers solutions to the prior art drawbacks, for instance by replacing gold wires as the first level interconnect with electrically conductive bumps electrically connecting the die active surface to the substrate. Accordingly, a thinner image sensor package can be obtained through the elimination of wire bonds, and the invention allows a better electrical performance through the reduction of the inductance and capacitance of the first level interconnects.

The invention also has the advantage of allowing smaller foot-print packages, for instance image sensors, which can be achieved at a relatively lower cost compared with conventional such packages.

The invention additionally allows a packaging structure in which the thermal performance of the package is improved by providing a direct heat dissipation path from the die to a printed circuit board.

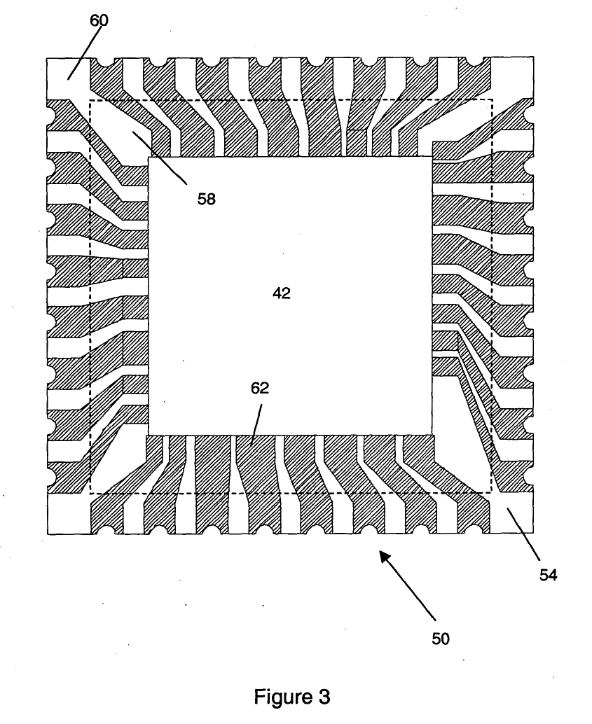

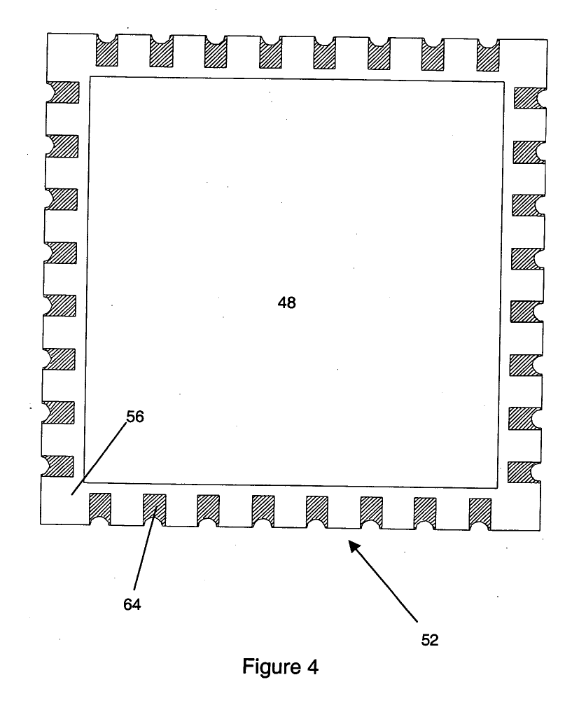

Referring to FIG. 2, it shows a cross-sectional view of a semiconductor packaging structure in accordance with a first embodiment of the invention. More particularly, this specific package shows a package for a flip-chip sensor, although the invention is not limited to such sensors, or even to sensors at all. FIG. 3 shows the semiconductor packaging structure of this embodiment, through line 3-3 of FIG. 2, looking from the second side. FIG. 4 shows the substrate of the semiconductor packaging structure of this embodiment, through line 4-4 of FIG. 2, looking from the first side.

The overall package, designated 30 includes a substrate 32, a semiconductor die 34, a cover glass 36, interconnects 38 between the semiconductor die 34 and substrate 32 and encapsulant 40 around the ends of the semiconductor die 34.

The volume defined between the extreme vertices of the substrate 32 is generally a parallelepiped, although the substrate is hollow, with the hollow extending from a first major side 44 through to a opposing second major side 46. In plan view, from either of the first and second opposing sides 44, 46, the outer surfaces of the substrate provide a rectangle.

The hollow within the substrate is made up of a first recess 42, in the first major side 44 and a second recess 48 in the second major side 46 (the underside in the orientation of FIG. 2), meeting within the substrate. These first and second recesses 42, 48 are also therefore first and second hollow portions. The substrate walls around the recess 48, near the second side, are thinner, in a direction parallel to the first and second sides 44, 46, than around the recess 42 in the first side 44. Thus, in cross-section, the substrate is stepped, as shown in FIG. 2.

In this embodiment, the substrate 32 is made up of two layers: a first, upper layer 50 and a second, lower layer 52. The first, upper layer 50 has a first, major outer surface, which is the first side 44 of the substrate. It also has a second, major surface 54. The second, lower layer 52 has a first, major surface 56 and a second, major outer surface, which is the second side 46 of the substrate. The second, major surface 54 of the first, upper layer 50 is mounted on and fused to the first, major surface 56 of the second, lower layer 52. The external walls of the two layers are aligned and are generally flush with each other.

Recess 42 extends through the first, upper layer 50, whilst recess 48 extends through the second, lower layer 52 and the walls of the first, upper layer 50, are thicker than those of the second, lower layer 52. As FIGS. 3 and 4 indicate, this leaves an exposed portion 58 of the second side 54 (the underside in the orientation of FIG. 2) of the first layer 50, around the central rectangular hollow 42, in that it is not covered by the first side 56 of the second layer 52. There is also a covered portion 60 of the second side 54 of the first layer 50, where the two layers overlap.

Metallized traces 62 are provided on the second side 54 of the first layer 50, on the exposed portion 58 and run generally outwards to covered portion 60 of the second side 54 of the first layer 50. Additionally, vias 64 extend around the side of the second layer 52, from its first side 56 to its second side 46, which is the mounting surface for the structure. The vias 64 end in mounting pads 70 in the second side 46. The vias 64 electrically contact the traces 62, when the two substrate layers are in contact with each other. The mounting pads 70 are, in use, mounted on a printed circuit board (PCB) (not shown).

The semiconductor die 34 is mounted in the recessed 48 underside of the substrate 32. In this embodiment the die includes a sensor chip 72, with a light-sensitive, active first side uppermost, facing towards the first side 44 of the substrate 32, and the opposing second side facing towards the second side 46 of the substrate 32. The relative sizes of die and substrate are such that the die is longer and wider than the hollow portion 42 of the first substrate layer 50 (although it only in fact need be longer or wider to work some aspects of the invention), but shorter and narrower than the recessed portion 48 of the second substrate layer 52. In this way, the edges 74 of the die 34 overlap the exposed portion 58 of the second side 54 of the first substrate layer 50.

The edges 74 of the semiconductor die 34 overlapping the exposed portion 58 of the second side 54 of the first substrate layer 50 have bond pads 76 in their upper surfaces. These are electrically connected to the sensor chip 72 (not shown). The positions of the bond pads 76 match the positions of the inner ends of traces 62 on the exposed portion 58 of the first substrate layer 50. The die 34 is attached to the matching traces 62 on the exposed portion 58 of the first layer 50 through interconnect bumps 38 on the bond pads 76, to form electrical connections. Thus electrical connection exists between the sensor chip 72 of the die and the mounting pads 70, without loose wires, by way of: bond pads 76, interconnect bumps 38, traces 62, and vias 64, with the outputs from and inputs to the sensor connected to predetermined mounting pads 70.

Interconnect bumps 38 act not only to connect the die 34 electrically to the substrate 32, but also to provide the mechanical mounting of the die 34 to the substrate 32. The bumps 38 also serve as thermal conduction paths to carry heat from the sensor chip 72 on the die 34 to the substrate 32. In this embodiment the interconnect bumps 38 are solder bumps but other types of bumps, for example: plated bumps, stud bumps or adhesive bumps could be used here instead or in other embodiments of the invention.

Sealant 40 surrounds the outermost edges of the die 34, enclosing any space between the die 34 and the recessed walls of the second substrate layer 52, as well as overlapping those edges slightly, on the lower, second side of the die 34. In this way the top surface of the die is inaccessible from the second side 46 of the substrate 32. The sealant in this embodiment is highly viscous, to avoid seepage and contamination of the first side of the die 34. The sealant also provides additional mechanical strength to keep the die in place.

Finally, there is a cover glass 36 attached and sealed to the first side 44 of the first substrate layer 50 to provides physical protection for the die 34 from the environment. The top surface of the die 34 is thus also inaccessible from the first side 44 of the substrate 32. The cover glass 36 serves to complete the enclosure and sealing of the top surface of the die 34, whilst allowing light to pass through and impinge upon the sensor chip 72.

In the above embodiment, the substrate 32 may be a PCB, the die 34 may be SiGe, the interconnects 38 solder bumps, the sealant 40 dam and fill epoxy, the traces 62 copper, the vias 68 copper, the mounting pads 70 copper, and the sensor chip 72 SiGe. However, the materials can be different within the scope of the invention.

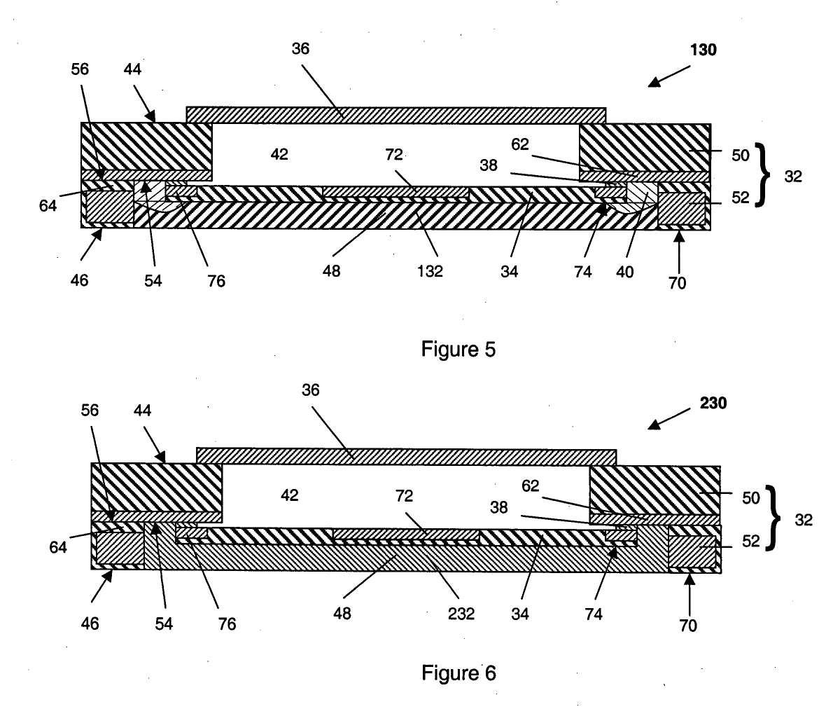

FIG. 5 is a side cross-sectional view of a semiconductor packaging structure 130 in accordance with a second embodiment of the invention. FIGS. 3 and 4 also apply to this embodiment. This embodiment uses the packaging structure 30 of the first embodiment and the above description therefore applies. However, in addition, a thermally conductive material encapsulant 132 (e.g. an epoxy) fills the rest of the recess 48 between the die 34 and the second side 46 of the substrate 32. This fully encapsulates the underside of the die 34 and enhances the thermal dissipation from the die to a PCB on which the package is mounted.

The underside 134 of the thermally conductive material 132 is flush with the level of the second side 46 of the second substrate layer 52 so as to provide good thermal contact with a PCB, for improved thermal conductance.

FIG. 6 is a side cross-sectional view of a semiconductor packaging structure 230 in accordance with a third embodiment of the invention. FIGS. 3 and 4 also apply to this embodiment. It too is very similar to the first embodiment. Where similar elements are used in both embodiments, the same reference numerals apply. Thus the above description of the first embodiment applies, except that in this embodiment the sealant is not limited to around the edges of the semiconductor die 34.

In the third embodiment a thermally conductive and electrically insulating encapsulant 232 (e.g. a highly viscous epoxy) fills the rest of the recess 48 between the die edges 74 and the recessed walls of the second substrate layer 52 and between the underside of the die 34 and the second side 46 of the substrate 32. Thus it occupies the same space as the sealant 80 and encapsulant 132 together occupy in the second embodiment. This fully encapsulates the underside of the die 34 and enhances the thermal dissipation from the die to a PCB on which the package is mounted.

As with the second embodiment, the underside 234 of the thermally conductive encapsulant 232 is flush with the level of the second side 46 of the second substrate layer 52 so as to provide good thermal contact with a PCB, for improved thermal conductance.

In both the second and third embodiments, the underside of the thermally conductive encapsulant is flush with the level of the second side of the second substrate layer. However, the encapsulant does not need to fill the rest of the recess completely nor need to extend as far down as the level of the second side of the second substrate layer. Preferably, however, it does not extend below that level, unless there is available space into which excess encapsulant can be deformed during mounting on a PCB, otherwise it may prevent good or stable contacts.

The above embodiments have a cover glass, which is typically a silicon-oxide glass. However, other glasses or plastics or other non-opaque, preferably transparent layers, can be used. Alternatively, the cover can be replaced with an electrically insulating encapsulant in the hollow portion 42 between the die and the first side 44 of the substrate 32. At least when the die is a sensor chip, such an encapsulant would be non-opaque to the frequencies which are to be sensed. When heat dissipation is at least preferred, the encapsulant could usefully be thermally conductive.

The described embodiments show the cover glass on top of the first side of the substrate. Alternatively, the first side of the substrate could be recessed, with the cover glass in that recess.

The invention is not limited to sensors. Other dies may be used. The package of the invention may even be constructed and arranged such that no light reaches the die from the first side of the substrate. For example, this could be achieved by means of an opaque cover instead of the glass cover, an opaque encapsulant in the hollow portion of the die or the first side of the substrate being solid, or at least not having a hole or recess connecting with the recess in the second side of the substrate.

The described embodiments differ in the use of sealant and/or encapsulant beneath the die. Other combinations and variations are possible, even to the extent of the only seal being between the top surface of the edges of the die and the exposed portion of the second side of the first substrate layer. Other possibilities include using a heat spreader in contact with the underside of the die, instead of the encapsulant, or in addition to the encapsulant to improve the rate of heat transfer to the encapsulant. The addition of a heat spreader (made from a material with high thermal conductivity—e.g. copper) will assist in extracting heat from the die; by providing a lower thermal resistance path from the die to the board on which is invention will be mounted.

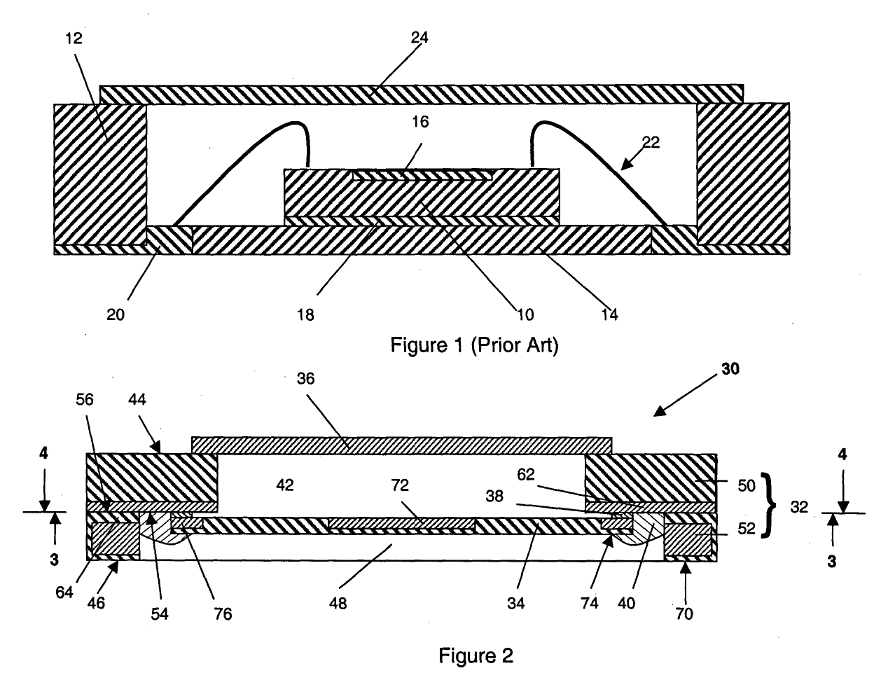

The packaging structure of this invention does not have to be wide enough and tall enough to accommodate loop wires between a die and its substrate. Instead the overall package can be shorter, thinner and/or narrower than in the prior art constructions, for instance that of FIG. 1. The present invention typically allows a lateral size reduction of 1 to 1.5 mm (wirebond length on both sides). Moreover, besides having a small footprint, and improved electrical performance, this invention also provides the opportunity to improve the thermal performance of the package, by providing a direct heat dissipation path from the die to the board, through the encapsulant which has a higher thermal conductivity than the ceramic of the prior art.

Various pads, vias, traces, bumps and connects have been mentioned. Other arrangements of those same components are possible or totally different arrangements of electrical connections, as long as there is an electrical path from the die to the mounting surface of the structure.

In the described embodiments the substrate 32 is made up of two layers 50, 52. However, the substrate could have more layers (three or four or more, if desired) or fewer (i.e., it would be a unitary substrate). The two layers of the embodiments are described as being fused. However, they could be glued, clamped, screwed or held together or otherwise mounted together in a number of other ways, as would readily be apparent to the person skilled in the art. These variations on the substrate could still with have the same stepped shape or have a variety of other shapes, for example with more steps, discontinuous steps or ledges or a non-parallelepiped volume. Moreover, whilst, in the described embodiments, each layer is itself a unitary structure, the layers can be made up of several components joined together, or possibly even separated. For instance, the lower part of the substrate does not need to surround the recess completely; it could just be made up of two end walls, one at each end of the structure, below the second side of the first layer. Thus, there could be gaps in the wall of the second layer, around the recess, as long as a seal between the die and substrate is kept.

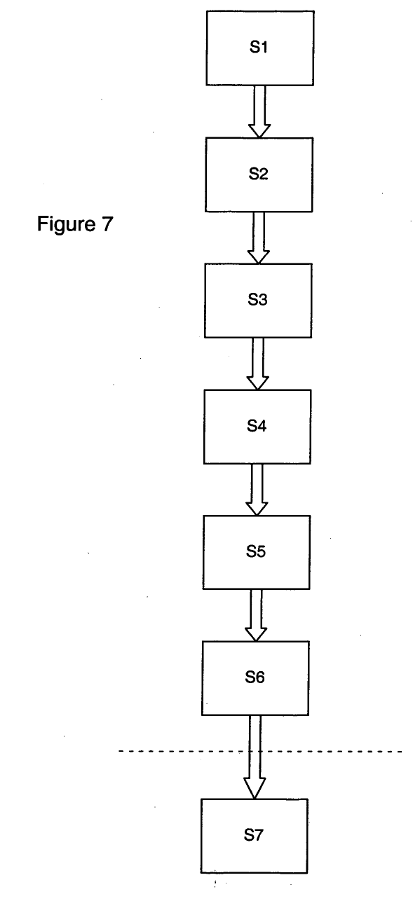

A method of assembling a packaging structure of the second embodiment, according to the invention will now be described with reference to FIG. 7.

Step S1 is the provision of the substrate 32 and the semiconductor die 34. In step S2, the semiconductor die 34 is inserted into the recess 48 of the substrate and held in place, with solder bumps 38 on the die 34 in contact with the traces 62 on the second side 54 of the first substrate layer 50. A solder reflow method is used in step S3 to melt and solidify the solder bumps, thereby electrically connecting the bumps 38 and traces 62 and bonding the die to the substrate.

The sealant 80 is deposited around the edge of the die, between the inner walls of the second substrate layer 52 and the die 34, in step S4, thereby sealing the first side of the die off from below. The encapsulant 132 is then filled into the remaining space of the recess 48 on the second side of the die, to the required level, in step S5. Finally, during assembly, in step S6, the glass cover 36 is adhered to the first surface 44 of the first substrate layer.

At a later time, when the package is to be mounted, there is a surface mounting step S7, in which it is surface mounted onto a PCB.

Whilst this process has been described in the specific order S1 to S7, certain variations are allowed. For instance the glass cover step could happen at any other point in the process. Additionally, the solder reflow, or equivalent steps could occur prior to insertion of the die into the recess, with only the setting (or curing or whatever) happening after insertion.

The invention has been described with reference to preferred embodiments. The scope of the invention, however, is by no means limited by these preferred embodiments. It will be appreciated that variations and modifications, whether explicitly given in the specification or not, such as differences in structure, dimension, and use of material, can be effected by a person skilled in the art without departing from the scope of the invention.

1. A packaging structure for a semiconductor device, comprising:
a substrate surface-mountable on a mounting surface of a circuit board, wherein the substrate has a first side facing away from the mounting surface and a second side being on the same side of the structure as the mounting surface;
a recess in the second side of the substrate;
a semiconductor die having a first side and a second side, and mounted in said recess, with the first side of the semiconductor die facing away from the mounting surface and a portion of the first side of the semiconductor die bonded to said substrate within the recess.

2. A structure according to claim 1, wherein said recess includes an exposed portion of the substrate facing the mounting surface and said portion of the first side of the die is bonded to said exposed portion.

3. A structure according to claim 2, wherein the bond between the die and the substrate is an electrical connection.

4. A structure according to claim 1, wherein said substrate has a hollow portion extending from the first side of the substrate to the recess.

5. A structure according to claim 1, wherein:
said substrate comprises first and second substrate layers, the first substrate layer having first and second opposing sides and the second substrate layer having first and second opposing sides;
the first side of the first substrate layer is the first side of the substrate and the second side of the second substrate layer is the second side of the substrate; and
the second side of the first substrate layer is mounted to the first side of the second substrate layer.

6. A structure according to claim 5, wherein the second substrate layer has inner walls defining a hollow portion extending from the first side of the second substrate layer to the second side of the second substrate layer, with the inner walls defining at least part of said recess.

7. A structure according to claim 6, wherein:
the first substrate layer has a hollow portion extending from the first side of the first substrate layer to the second side of the first substrate layer;
the hollow portion through the first substrate layer is smaller than the hollow portion through the second substrate layer, such that where the second side of the first substrate layer is mounted to the first side of the second substrate layer, a portion of the second side of the first substrate layer is exposed, not being covered by the first side of the second substrate layer; and
the exposed portion of first substrate layer defines at least part of the recess.

8. A structure according to claim 6, wherein the hollow portion defined by the hollow portion is rectangular.

9. A structure according to claim 1, further comprising electrical connections running from where the die is bonded to said recess to the mounting surface.

10. A structure according to claim 9, further comprising bond pads connecting said die to said electrical connections.

11. A structure according to claim 1, wherein said die has edges and further comprising sealant sealing between the edges of said die and said substrate.

12. A structure according to claim 11, wherein said sealant comprises a highly viscous material.

13. A structure according to claim 1, further comprising a thermally conductive and electrically insulating encapsulant in said recess, on the second side of the semiconductor die.

14. A structure according to claim 13, wherein said encapsulant comprises a viscous, thermally conductive material.

15. A structure according to claim 14, wherein the encapsulant is flush with the level of the second side of the substrate.

16. A structure according to claim 1, wherein said die is a sensor chip.

17. A structure according to claim 1, further comprising a non-opaque portion mounted to the substrate on the same side of the structure as the first side of the substrate.

18. A structure according to claim 17, wherein said non-opaque portion is a transparent cover on the first side of said substrate.
